(19) United States
(12) Patent Application Publication
(10) Pub. No.: US 2012/0067625 A1
(43) Pub. Date: Mar. 22, 2012

(54) SUSPENSION BOARD WITH A CIRCUIT FOR USE IN A HARD DISK DRIVE

(75) Inventor: Masaki Mizutani, Osaka (JP)

(73) Assignee: NITTO DENKO CORPORATION, Osaka (JP)

(21) Appl. No.: 13/207,032

(22) Filed: Aug. 10, 2011

(30) Foreign Application Priority Data
Sep. 22, 2010 (JP) 2010-212384

(51) Int. Cl. H05K 1/05

(52) U.S. Cl. 174/255

(57) ABSTRACT

A suspension board with a circuit for use in a hard disk drive shows a small change in PSA (attitude angle) relative to a change in humidity and can support a slider including a magnetic head in a stable and highly precise manner. The suspension board with a circuit for use in a hard disk drive includes a substrate made of metal, an undercoat insulating layer provided on the substrate made of metal, a conductive layer provided on the undercoat insulating layer 3, and a cover insulating layer provided so as to cover the conductive layer. The tensile storage modulus at 25° C. of at least one of the undercoat insulating layer 3 and the cover insulating layer 5 is set to 0.1 to 1.0 GPa.

### BACKGROUND OF THE INVENTION

1. Field of the Invention

The present invention relates to a suspension board with a circuit for use in a hard disk drive.

2. Description of the Related Art

In a hard disk drive (hereinafter, referred to as “HDD”) to be used as a storage device (recording means) in a computer, electronic equipment, or the like, a discoidal magnetic disk (platter) and a magnetic head (slider) are relatively rotated, and through use of a pressure of an air flow caused by the rotation, an interval (gap) between the magnetic head and the above-mentioned magnetic disk is kept at an appropriate distance by: (I) supporting the above-mentioned magnetic head lifted so that the magnetic head does not come into contact with the magnetic disk; and (II) pressing the above-mentioned magnetic head onto the magnetic disk side through use of elasticity of a suspension, to thereby balance the pressing force and the upward pressure of the above-mentioned air flow.

As a structure in which the magnetic head of the HDD described above is supported and implemented, there has been proposed and put into practical use a suspension board with a circuit having a circuit (wiring) pattern for connecting the magnetic head to means for controlling a device integrally formed on a suspension board of an arm shape having elasticity (see JP-A-2008-310946).

The structure of the suspension board with a circuit for use in a HDD has, for example, a construction in which an insulating layer made of a polyimide resin or the like is formed on a stainless-steel foil substrate, and a conductive layer (thin film) of a predetermined pattern made of copper or the like is formed as a circuit (electrical wiring) thereon. In addition, an electrically conductive portion serving as a terminal is formed on the above-mentioned conductive layer or on the surface, and an insulating covering layer for covering the above-mentioned insulating layer and conductive layer is laminated on the entire surface excluding the terminal region. Then, a slider including a magnetic head is mounted (implemented) on the leading end (tapered portion) of the arm shape (see JP-A-H10-265572).

By the way, in accordance with an improvement in recording density of a magnetic disk of recent years, a HDD is required to more precisely adjust a pitch static attitude (PSA: attitude angle) of the above-mentioned slider (magnetic head) from a magnetic disk. Also in the above-mentioned suspension board with a circuit for use in a HDD, there is a demand for making a change in PSA described above due to changes in temperature and humidity as small as possible.

Conventionally, a measure to make coefficients of thermal expansion of a substrate and a conductive layer close to those of an undercoat insulating layer and a cover insulating layer has been adopted in order to suppress a change in PSA of the slider associated with a change in temperature. Further, a measure to make coefficients of hygroscopic expansion of the substrate and the conductive layer close to those of the undercoat insulating layer and the cover insulating layer has been adopted in order to suppress a change in PSA of the slider associated with a change in humidity. However, it is difficult to make the coefficients of thermal expansion and coefficients of hygroscopic expansion of an undercoat insulating material and a cover insulating material each made of resin simultaneously close to those of the substrate and the conductive layer each made of metal. In particular, the coefficients of hygroscopic expansion of the substrate and the conductive layer made of metal are substantially 0 (zero). It is therefore extremely difficult to make the coefficients of hygroscopic expansion of the undercoat insulating material and the cover insulating material each made of resin close to those of the above-mentioned substrate and conductive layer each made of metal. Therefore, in JP-A-2008-310946 above or the like, in actuality, the photosensitivity and other requisite physical properties of the above-mentioned resin materials are sacrificed by making the coefficients of hygroscopic expansion of the above-mentioned resin materials close to those of the metal materials.

### SUMMARY OF THE INVENTION

A suspension board is provided with a circuit for use in a hard disk drive, which shows a small change in PSA (attitude angle) relative to a change in humidity and can support a slider including a magnetic head in a stable and highly precise manner.

A first aspect of a suspension board with a circuit for use in a hard disk drive resides in a suspension board with a circuit for use in a hard disk drive, including: a substrate made of metal; an undercoat insulating layer provided on the above-mentioned substrate made of metal; a conductive layer formed of a predetermined wiring circuit pattern provided on the above-mentioned undercoat insulating layer; and a cover insulating layer provided so as to cover the above-mentioned conductive layer, and is constituted so that at least one of the above-mentioned undercoat insulating layer and cover insulating layer has a tensile storage modulus at 25° C. of 0.1 to 1.0 GPa.

Further, a second aspect of a suspension board with a circuit for use in a hard disk drive resides in a suspension board with a circuit for use in a hard disk drive, including: a substrate made of metal; an undercoat insulating layer provided on the above-mentioned substrate made of metal; a first conductive layer formed of a predetermined wiring circuit pattern provided on the above-mentioned undercoat insulating layer; an intermediate insulating layer provided on the above-mentioned first conductive layer; a second conductive layer formed of a predetermined wiring circuit pattern provided on the above-mentioned intermediate insulating layer; and a cover insulating layer provided on the above-mentioned second conductive layer, and is constituted so that at least one insulating layer of the above-mentioned undercoat insulating layer, intermediate insulating layer, and cover insulating layer has a tensile storage modulus at 25° C. of 0.1 to 1.0 GPa.

That is, various physical properties of a resin material constituting a covering layer (insulating layer) of a suspension board with a circuit for use in a HDD have been studiedA tensile storage modulus of an insulating resin material in place of a coefficient of hygroscopic expansion, which has conventionally been studied, as a factor influencing a change amount in PSA of the above-mentioned slider due to a humidity in the above-mentioned suspension board. The tensile storage modulus is employed as an indicator. Then, the expansion or shrinkage of the suspension board associated with a change in humidity is suppressed more effectively by setting the tensile storage modulus at 25° C. of the above-mentioned insulating layer to 0.1 to 1.0 GPa rather than making coefficients of hygroscopic expansion of an undercoat insulating material and a cover insulating material each made of resin close to those of a substrate and a conductive layer each made of metal as said previously. It should be noted that the “tensile storage modulus” used herein refers to a value at 25° C. for a storage modulus (E′) measured by a tensile mode among dynamic viscoelasticity values, which are measured in accordance with JIS K 7244-4: 1999 “Plastics-Determination of dynamic mechanical properties-Part 4: Tensile vibration-Non-resonance method.” Further, sample preparation and measurement procedures for measuring the above-mentioned “tensile storage modulus” are described in detail in the section “Modes for carrying out the Invention” described later.

As described above, the suspension board with a circuit for use in a HDD according to the first aspect of the present invention includes: a substrate made of metal; an undercoat insulating layer provided on the above-mentioned substrate made of metal; a conductive layer formed of a predetermined wiring circuit pattern provided on the above-mentioned undercoat insulating layer; and a cover insulating layer provided so as to cover the above-mentioned conductive layer, and is constituted so that at least one of the above-mentioned undercoat insulating layer and the above-mentioned cover insulating layer has a tensile storage modulus at 25° C. of 0.1 to 1.0 GPa. Therefore, the suspension board with a circuit for use in a HDD hardly undergoes expansion and shrinkage due to a change in humidity. As a result, the suspension board with a circuit for use in a HDD shows a small change in PSA of the slider of the HDD relative to a change in humidity and can support the above-mentioned slider provided with a magnetic head in a stable and highly precise manner.

Further, in the above-mentioned suspension board with a circuit for use in a HDD, in which the above-mentioned undercoat insulating layer and cover insulating layer each have a tensile storage modulus at 25° C. of 0.1 to 1.0 GPa, all insulating layers each involved in a change in PSA hardly undergo expansion or shrinkage due to a change in humidity. As a result, the suspension board with a circuit for use in a HDD shows an additionally small change in PSA of the slider of the HDD due to a change in humidity and can support the slider in a more stable manner.

In addition, the suspension board with a circuit for use in a HDD, in which the above-mentioned undercoat insulating layer and cover insulating layer are each composed of a photosensitive resin composition containing the following component (A) and component (B), can support the above-mentioned slider including a magnetic head in a more stable and highly precise manner without lowering the photosensitivity and other requisite physical properties of resin.

(A) a 1,4-dihydropyridine derivative represented by the following general formula (1).

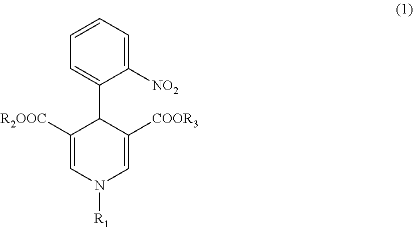

[In the formula (1): R₁ represents an alkyl group having 1 to 3 carbon atoms; and R₂ and R₃ each represent a hydrogen atom or an alkyl group having 1 or 2 carbon atoms and may be identical to or different from each other.]
(B) a polyimide resin obtained by a reaction of a tetracarboxylic acid dianhydride and a diamine compound which has two terminals each having an amine structure and has a polyether structure, or a precursor resin thereof.

Further, the suspension board with a circuit for use in a HDD according to the second aspect of the present invention includes: a substrate made of metal; an undercoat insulating layer provided on the above-mentioned substrate made of metal; a first conductive layer formed of a predetermined wiring circuit pattern provided on the above-mentioned undercoat insulating layer; an intermediate insulating layer provided on the above-mentioned first conductive layer; a second conductive layer formed of a predetermined wiring circuit pattern provided on the above-mentioned intermediate insulating layer; and a cover insulating layer provided on the above-mentioned second conductive layer, and is constituted so that at least one insulating layer of the above-mentioned undercoat insulating layer, intermediate insulating layer, and cover insulating layer has a tensile storage modulus at 25° C. of 0.1 to 1.0 GPa. Therefore, the suspension board with a circuit for use in a HDD hardly undergoes expansion or shrinkage due to a change in humidity in the same manner as in the suspension board with a circuit for use in a HDD according to the first aspect. As a result, the suspension board with a circuit for use in a HDD shows a small change in PSA of the slider of the HDD relative to a change in humidity and can support the above-mentioned slider including a magnetic head in a stable and highly precise manner.

Further, the above-mentioned suspension board with a circuit for use in a HDD, in which all of the above-mentioned undercoat insulating layer, intermediate insulating layer, and cover insulating layer have a tensile storage modulus at 25° C. of 0.1 to 1.0 GPa, more hardly undergoes expansion or shrinkage due to a change in humidity. As a result, the suspension board with a circuit for use in a HDD shows an additionally small change in PSA of the slider of the HDD due to a change in humidity and can support the slider in a more stable manner.

In addition, the suspension board with a circuit for use in a HDD, in which the above-mentioned undercoat insulating layer, intermediate insulating layer, and cover insulating layer are each made of a photosensitive resin composition containing the following component (A) and component (B), is preferred because the suspension board can support the above-mentioned slider including a magnetic head in a more stable and highly precise manner without lowering the photosensitivity and other requisite physical properties of resin.

(A) a 1,4-dihydropyridine derivative represented by the following general formula (1).

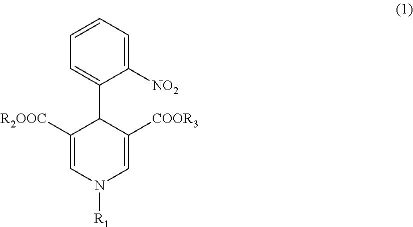

[In the formula (1): R₁ represents an alkyl group having 1 to 3 carbon atoms; and R₂ and R₃ each represent a hydrogen atom or an alkyl group having 1 or 2 carbon atoms and may be identical to or different from each other.]
(B) a polyimide resin obtained by a reaction of a tetracarboxylic acid dianhydride and a diamine compound which has two terminals each having an amine structure and has a polyether structure, or a precursor resin thereof.

### BRIEF DESCRIPTION OF THE DRAWINGS

FIG. 1A is a perspective view illustrating a construction of a suspension board with a circuit for use in a HDD and FIG. 1B is a schematic cross-sectional view illustrating a structure of a portion P of FIG. 1A.

FIG. 2 is a schematic view illustrating a production method for a suspension board with a circuit for use in a HDD.

FIG. 3 is a schematic view illustrating the production method for a suspension board with a circuit for use in a HDD.

FIG. 4 is a schematic view illustrating the production method for a suspension board with a circuit for use in a HDD.

FIG. 5 is a schematic view illustrating the production method for a suspension board with a circuit for use in a HDD.

FIG. 6 is a schematic view illustrating the production method for a suspension board with a circuit for use in a HDD.

FIG. 7 is a schematic view illustrating the production method for a suspension board with a circuit for use in a HDD.

FIG. 8 is a schematic view illustrating the production method for a suspension board with a circuit for use in a HDD.

FIG. 9 is a schematic view illustrating the production method for a suspension board with a circuit for use in a HDD.

FIG. 10 is a schematic view illustrating the production method for a suspension board with a circuit for use in a HDD.

FIG. 11 is a schematic view illustrating the production method for a suspension board with a circuit for use in a HDD.

FIG. 12 is a schematic view illustrating the production method for a suspension board with a circuit for use in a HDD.

FIG. 13 is a schematic view illustrating the production method for a suspension board with a circuit for use in a HDD.

FIG. 14 is a schematic view illustrating the production method for a suspension board with a circuit for use in a HDD.

FIG. 15 is a schematic view illustrating the production method for a suspension board with a circuit for use in a HDD.

FIG. 16 is a schematic view illustrating the production method for a suspension board with a circuit for use in a HDD.

FIG. 17 is a schematic view illustrating the production method for a suspension board with a circuit for use in a HDD.

FIG. 18A is a lateral view illustrating a measurement method for a change in PSA of a suspension board with a circuit for evaluation produced in Examples and FIG. 18B is a front view illustrating the measurement method.

### DETAILED DESCRIPTION OF THE INVENTION

Next, embodiments of the present invention are described in detail with reference to the drawings.

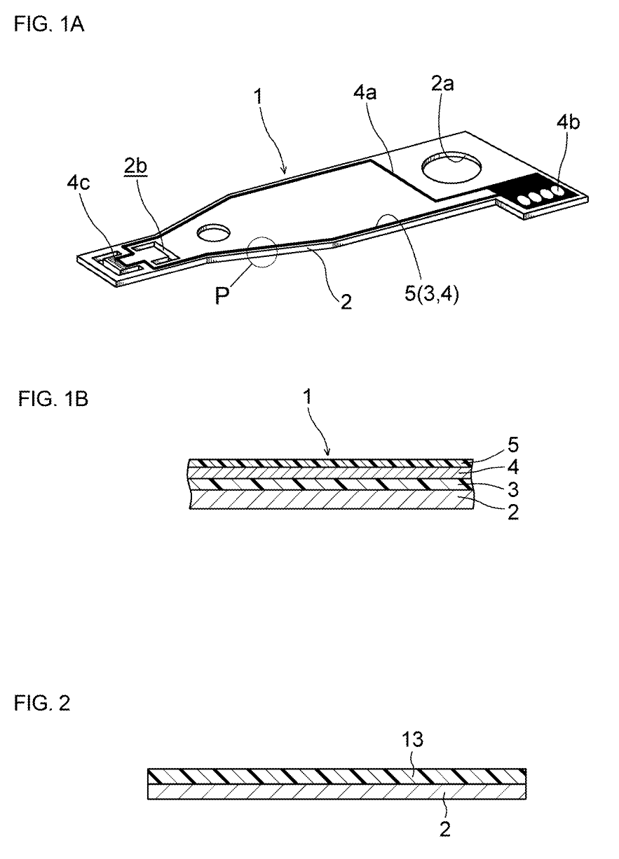

FIG. 1A is a perspective view illustrating a construction of a suspension board with a circuit for use in a HDD in an embodiment of the present invention, and FIG. 1B is an enlarged schematic cross-sectional view illustrating a structure of a portion P of FIG. 1A. It should be noted that, in FIG. 1A, the illustration of an insulating layer (undercoat insulating layer 3) and a conductive layer 4 to be covered with a cover layer (cover insulating layer 5) is omitted.

As illustrated in FIGS. 1A and 1B, the suspension board 1 with a circuit for use in a HDD in this embodiment is constituted of: a substrate 2 made of metal; an undercoat insulating layer 3 provided on the substrate 2; a conductive layer 4 provided on the undercoat insulating layer 3; a cover insulating layer 5 provided so as to cover the conductive layer 4; and the like. The suspension board 1 with a circuit for use in a HDD has a feature different from a conventional suspension board in that the tensile storage modulus at 25° C. of each of the above-mentioned undercoat insulating layer 3 and cover insulating layer 5 is set to 0.1 to 1.0 GPa.

By virtue of the above-mentioned construction, in the suspension board 1 with a circuit for use in a HDD, irrespective of coefficients of hygroscopic expansion of the undercoat insulating layer 3 and the cover insulating layer 5, the expansion or shrinkage of the suspension board associated with a change in humidity is extremely small. Therefore, the above-mentioned suspension board 1 with a circuit for use in a HDD hardly undergoes warping or strain attributed to expansion, shrinkage, or the like due to a change in humidity. Further, even when a slider including a magnetic head is implemented on terminal portion 4c of the above-mentioned conductive layer 4 for a slider and a shaft or the like is inserted through hole 2a of the above-mentioned substrate 2 and supported pivotally, the suspension board shows a small change in PSA (attitude angle) of the above-mentioned slider relative to a change in humidity and can support the slider in a stable and highly precise manner so that the slider maintains a proper gap from the magnetic disk.

It should be noted that the suitable range of the tensile storage modulus at 25° C. of each of the undercoat insulating layer 3 and cover insulating layer 5 after curing described above is generally 0.1 to 1.0 GPa, more preferably 0.15 to 0.9 GPa, still more preferably 0.2 to 0.8 GPa. The tensile storage modulus at 25° C. of each of the above-mentioned insulating layers 3 and 5 is measured as described below. That is, a film (insulating layer) made of a photosensitive resin composition is produced, and the film is cut into a piece measuring 5 mm wide by 30 mm long to produce a sample for measurement. Then, the above-mentioned sample was measured for its dynamic viscoelasticity (E′) in the range of 0 to 50° C. (temperature rising rate 5° C./min) while drawing the sample under the condition of a frequency of 1 Hz using a viscoelasticity measurement device RSA III (manufactured by Rheometric Scientific), and a value at 25° C. was read out.

Further, when the tensile storage modulus at 25° C. of each of the above-mentioned insulating layers 3 and 5 is less than 0.1 GPa, there is a tendency that the surface of each of the insulating layers 3 and 5 has tack property and becomes easy to stick to another surface, resulting in a deterioration in handleability. Further, when the tensile storage modulus at 25° C. of each of the above-mentioned insulating layers 3 and 5 is more than 1.0 GPa, there is a tendency that the expansion or shrinkage of each of the insulating layers 3 and 5 due to a change in humidity becomes large, resulting in an increase in change in PSA of the slider.

The structure of the above-mentioned suspension board 1 with a circuit for use in a HDD is described in detail.

The above-mentioned substrate 2 made of metal to be used is, for example, one formed by punching a metal thin plate (foil) such as a stainless-steel foil or an aluminum foil into a predetermined shape. The metal foil to be suitably used is generally one having a thickness of 10 to 60 μm, especially 15 to 30 μm from the viewpoint of vibration characteristics. It should be noted that the hole 2a, through which the suspension board 1 with a circuit for use in a HDD is inserted into a shaft of a stepping motor or the like (not shown) and supported pivotally, is provided on one end of the substrate 2 (on the right side of the figure and the base side of the board 1). Further, a gimbal for stabilizing an attitude angle of a slider (not shown) including a magnetic head with substantially U-shaped slits 2b and 2b is formed on the other end side of the substrate 2 (on the left side of the figure and the tip side of the board 1).

Further, the conductive layer 4 constituting the above-mentioned circuit is formed by plating copper or the like. As illustrated in FIG. 1, a terminal portion 4b for control necessary for connection to means for controlling a HDD is provided on one end (on the base side) of the conductive layer and the terminal portion 4c for a slider for connecting and implementing the above-mentioned slider is formed at the site positioned in the above-mentioned gimbal on the other end (on the tip side) of the conductive layer. It should be noted that the remaining narrow line site of the conductive layer 4 is a wiring portion 4a for connecting those portions. Further, the conductive layer 4 actually has a multi-layer structure, and one or two or more undercoat conductive layers (not shown) for improving the adhesiveness of the conductive layer 4 to the resin are interposed between the above-mentioned conductive layer 4 formed by plating and the undercoat insulating layer 3 (made of resin). Details about the undercoat conductive layer are described in a production method described later.

In addition, as described above, the tensile storage modulus at 25° C. of each of the undercoat insulating layer 3 placed between the above-mentioned substrate 2 and conductive layer 4 and the cover insulating layer 5 provided so as to cover the conductive layer 4 is set to 0.1 to 1.0 GPa.

A resin constituting the undercoat insulating layer 3 and the cover insulating layer 5 is, for example, a photosensitive resin composition made of a polyimide resin or the like. The photosensitive resin composition is designed and blended so that it has such property as being cured through irradiation with light rays such as electron rays or ultraviolet rays and has a tensile storage modulus at 25° C. after curing of 0.1 to 1.0 GPa.

Further, the above-mentioned photosensitive resin composition can easily form an insulating layer (insulating film) of a required pattern on the above-mentioned substrate 2 by employing a photolithographic method or the like. For example, a film made of the above-mentioned photosensitive resin composition is formed on the substrate 2 through application or the like, and then irradiated with electron rays, ultraviolet rays, or the like via a mask having a predetermined opening pattern to cure a necessary portion. After that, the resultant is subjected to development with a developing solution and a non-cured unnecessary portion is washed off. Thus, an undercoat insulating layer 3 and a cover insulating layer 5 of a predetermined pattern may be obtained.

The photosensitive resin composition (insulating material resin) constituting each of the undercoat insulating layer 3 and the cover insulating layer 5 of the above-mentioned suspension board with a circuit for use in a HDD may be specifically suitably exemplified by a resin material containing the following component

(A) and component (B):
(A) a 1,4-dihydropyridine derivative represented by the following general formula (1);

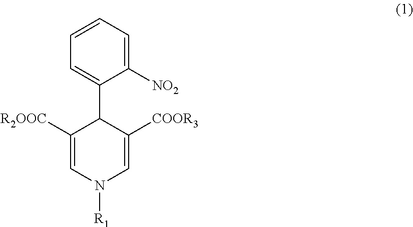

In the formula (1): R₁ represents an alkyl group having 1 to 3 carbon atoms; and R₂ and R₃ each represent a hydrogen atom or an alkyl group having 1 or 2 carbon atoms and may be identical to or different from each other; and
(B) a polyimide resin obtained by a reaction of a tetracarboxylic acid dianhydride and a diamine compound which has two terminals each having an amine structure and has a polyether structure (hereinafter, referred to as “PE diamine compound”), or a precursor resin thereof.

The PE diamine compound to be used in the above-mentioned component (B) is preferred in terms of reducing a tensile storage modulus at 25° C. of a polyimide resin. The PE diamine compound is a compound which has a polyether structure and has at least two terminals each having an amine structure, and is exemplified by a terminal diamine having a polypropylene glycol structure, a terminal diamine having a polyethylene glycol structure, a terminal diamine having a polytetramethylene glycol structure, and a terminal diamine having a plurality of those structures.

The polyether structure possessed by the above-mentioned PE diamine compound is a structure having two or more alkyleneoxy groups each represented by -A-O— (A represents an alkylene group and O represents an oxygen atom). The alkylene group as the above-mentioned unit A has generally 1 to 10 carbon atoms, preferably 2 to 5, and is, for example, methylene, ethylene, propylene, or butylene. It should be noted that a plurality of alkyleneoxy groups may be identical to or different from each other. Further, the alkylene group as the above-mentioned unit A may have a substituent (for example, a methyl group, a polyether group, or an amino polyether group).

Further, the amine structures at two terminals possessed by the above-mentioned PE diamine compound may be identical to or different from each other, and may be any of primary to tertiary amines. Of those, primary amine is preferred. The amine structure is, for example, methylamine, ethylamine, or propylamine. Of those, propylamine is preferred.

It should be noted that the above-mentioned PE diamine compound has a number average molecular weight of preferably 500 or more, more preferably 1,000 to 5,000.

The above-mentioned PE diamine compound is specifically exemplified by compounds represented by the following formulae (2) to (5).

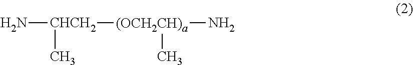

In the formula (2), a represents an integer of 2 or more, preferably 5 to 80.

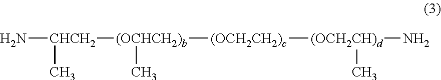

In the formula (3), b, c, and d each represent an integer of 0 or more, provided that b+c+d equals 2 or more, preferably 5 to 50.

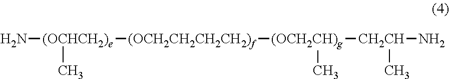

In the formula (4), e, f, and g each represent an integer of 0 or more, provided that e+f+g equals 2 or more, preferably 5 to 30.

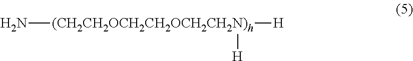

In the formula (5), h represents an integer of 1 or more, preferably 1 to 4.

Meanwhile, in the reaction (synthesis) of the tetracarboxylic acid dianhydride and the above-mentioned PE diamine compound in the component (B), in addition to the PE diamine compound (having a polyether structure), another kind of diamine compound free of any polyether structure is preferably used in combination.

The diamine compound to be preferably used in combination during the above-mentioned synthesis may be, for example, the following aliphatic diamine and aromatic diamine. The aliphatic diamine is, for example, ethylenediamine, hexamethylenediamine, 1,8-diaminooctane, 1,10-diaminodecane, 1,12-diaminododecane, 4,9-dioxa-1,12-diaminododecane, or 1,3-bis(3-aminopropyl)-1,1,3,3-tetramethyldisiloxane (α,ω-bisaminopropyltetramethyldisiloxane). The aliphatic diamine has a molecular weight of generally 50 to 1,000, preferably 100 to 300.

The above-mentioned aromatic diamine is, for example, 4,4′-diaminodiphenyl ether, 3,4′-diaminodiphenyl ether, 3,3′-diaminodiphenyl ether, m-phenylenediamine, p-phenylenediamine, 4,4′-diaminodiphenylpropane, 3,3′-diaminodiphenylpropane, 4,4′-diaminodiphenylmethane, 3,3′-diaminodiphenylmethane, 4,4′-diaminodiphenylsulfide, 3,3′-diaminodiphenylsulfide, 4,4′-diaminodiphenylsulfone, 3,3′-diaminodiphenylsulfone, 1,4-bis(4-aminophenoxy)benzene, 1,3-bis(4-aminophenoxy)benzene, 1,3-bis(3-aminophenoxy)benzene, 1,3-bis(4-aminophenoxy)-2,2-dimethylpropane, or 4,4′-diaminobenzophenone. Of those, 4,4′-diaminodiphenyl ether and p-phenylenediamine are preferred.

In addition, the tetracarboxylic acid dianhydride to be used in the component (B) is, for example, 3,3′,4,4′-biphenyltetracarboxylic acid dianhydride, 2,2′,3,3′-biphenyltetracarboxylic acid dianhydride, 3,3′,4,4′-benzophenonetetracarboxylic acid dianhydride, 2,2′,3,3′-benzophenonetetracarboxylic acid dianhydride, 4,4′-oxydiphthalic acid dianhydride, 2,2-bis(2,3-dicarboxyphenyl)hexafluoropropane dianhydride, 2,2-bis(3,4-dicarboxyphenyl) hexafluoropropane dianhydride (6FDA), bis(2,3-dicarboxyphenyl)methane dianhydride, bis(3,4-dicarboxyphenyl)methane dianhydride, bis(2,3-dicarboxyphenyl)sulfone dianhydride, bis(3,4-dicarboxyphenyl)sulfone dianhydride, pyromellitic acid dianhydride, or ethylene glycol bistrimellitic acid dianhydride. Of those, 3,3′,4,4′-biphenyltetracarboxylic acid dianhydride, 4,4′-oxydiphthalic acid dianhydride, 2,2-bis(3,4-dicarboxyphenyl)haxafluoropropane dianhydride (6FDA), or pyromellitic acid dianhydride is preferred. It should be noted that they are used alone or in combination of two or more kinds thereof.

Further, in the component (B), the polyimide resin obtained by a reaction of the tetracarboxylic acid dianhydride and the PE diamine compound, or the precursor resin thereof may be exemplified by compounds represented by the following formulae (6) to (9). It should be noted that, in the following formulae (6) to (9), Ar represents a structure containing at least one aromatic ring. Further, Ar preferably has 6 to 30 carbon atoms and represents, for example, a benzene ring, biphenyl, or diphenyl ether.

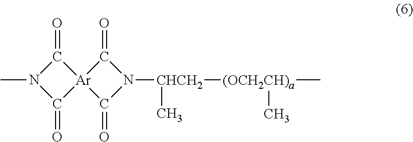

In the formula (6), a represents an integer of 2 or more, preferably 5 to 80.

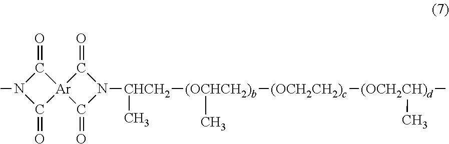

In the formula (7), b, c, and d each represent an integer of 0 or more, provided that b+c+d equals 2 or more, preferably 5 to 50.

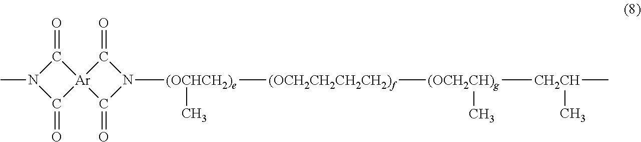

In the formula (8), e, f, and g each represent an integer of 0 or more, provided that e+f+g equals 2 or more, preferably 5 to 30.

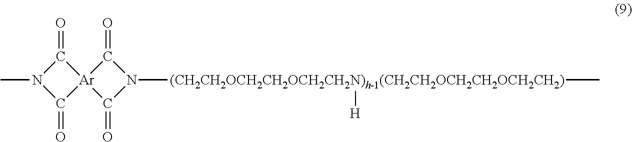

In the formula (9), h represents an integer of 1 or more, preferably 1 to 4.

Next, a production method for the above-mentioned suspension board with a circuit for use in a HDD is described with reference to the drawings. FIG. 2 to FIG. 17 are each a schematic view illustrating a production method for a suspension board with a circuit for use in a HDD in this embodiment.

In the production of the suspension board 1 with a circuit for use in a HDD in this embodiment, first, as illustrated in FIG. 2, a solution of the photosensitive resin composition containing the component (A) and component (B) (hereinafter, referred to as “PI photosensitive resin composition”) described in the above-mentioned embodiment is applied onto the entire surface of a stainless-steel foil substrate 2 having a thickness of 5 to 30 μm by a comma coat method, a fountain coat method, or the like so that the resultant resin layer has a thickness of 2 to 20 μm, preferably 3 to 15 μm, heated at 60 to 200° C., preferably 80 to 180° C., and formed into a film, to thereby form a coating film 13 of the above-mentioned PI photosensitive resin composition (which is to serve as the undercoat insulating layer 3 later).

Next, the coating film 13 of the PI photosensitive resin composition is irradiated with ultraviolet rays via an appropriate photomask and exposed in a predetermined pattern. Here, the exposure dose falls within the range of 50 to 2,000 mJ/cm², preferably 100 to 1,500 mJ/cm² and the exposure wavelength falls within the range of generally 200 to 450 nm, preferably 240 to 420 nm.

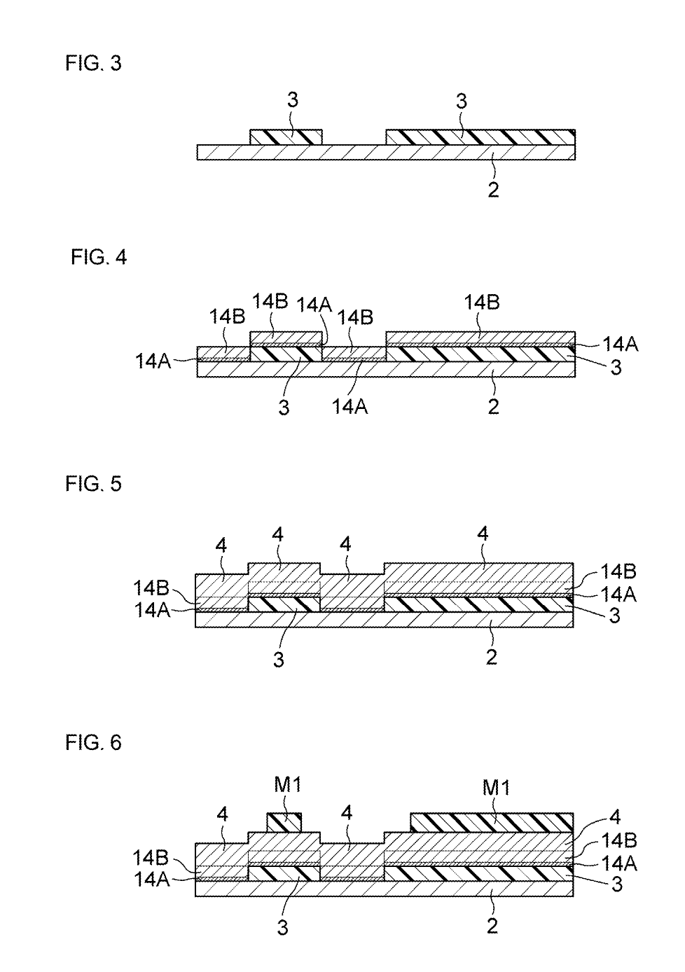

After the exposure, the coating film 13 is heated at a temperature of 90 to 210° C., preferably 100 to 200° C. for about 1 to 20 minutes (post-exposure heating) and then subjected to alkali developing treatment. After that, the above-mentioned patterned coating film 13 of the PI photosensitive resin composition was cured with heating at 150 to 400° C. over about 1 to 180 minutes, and as illustrated in FIG. 3, a patterned undercoat insulating layer 3 formed of a PI photosensitive resin layer was formed on the stainless-steel foil substrate 2.

Next, as illustrated in FIG. 4, a thin film (undercoat conductive layer 14A) made of chromium or titanium and a thin film (undercoat conductive layer 14B) made of copper are each successively and continuously formed as the above-mentioned undercoat conductive layer on the upper surface of the stainless-steel foil substrate 2 provided with the undercoat insulating layer 3 by sputtering. The above-mentioned thin film 14A made of chromium or titanium has an effect of improving the adhesiveness of the thin film 14B made of copper to the undercoat insulating layer 3. Here, it is preferred that the above-mentioned undercoat conductive layer 14A have a thickness in the range of 10 to 60 nm and the undercoat conductive layer 14B have a thickness in the range of 30 to 200 nm.

After that, as illustrated in FIG. 5, a conductive layer 4 made of copper having a thickness of about of 2 to 15 μm is formed by carrying out electrolytic plating on the above-mentioned undercoat conductive layer 14B.

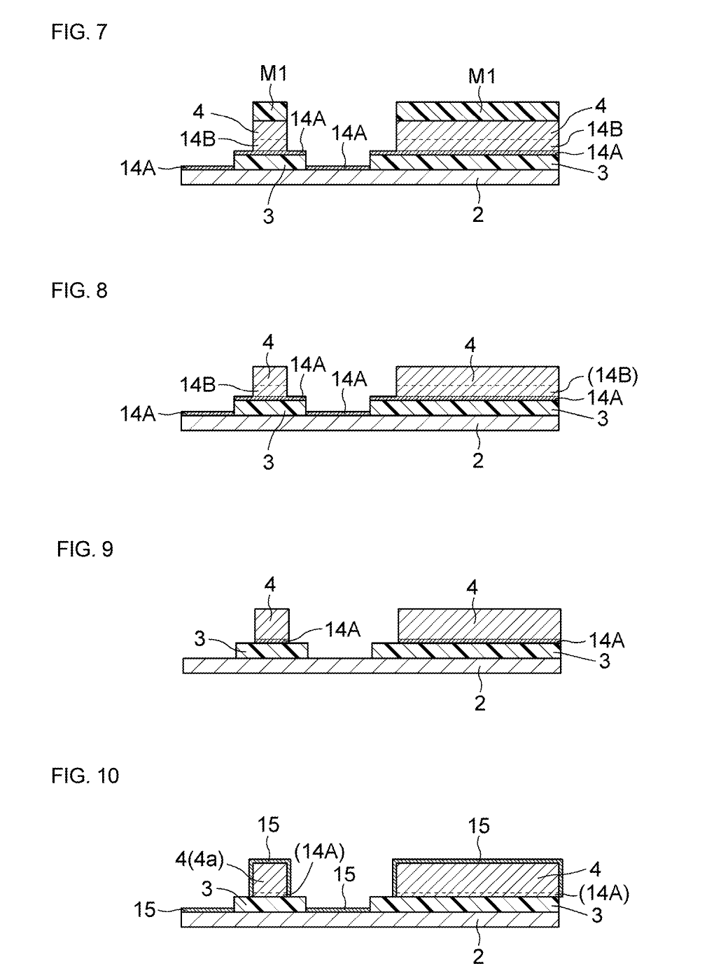

Next, as illustrated in FIG. 6, a patterned mask M1 made of a photo resist or a dry film laminate is formed on the conductive layer 4, exposure and developing treatment (etching) are carried out and the conductive layer 4 in a non-patterned portion is removed as illustrated in FIG. 7. After that, the above-mentioned mask M1 is removed, and the conductive layer 4 is formed as a predetermined circuit pattern as illustrated in FIG. 8. It should be noted that the etching for the conductive layer 4 made of copper (and the undercoat conductive layer 14B) is preferably alkali etching. Further, the undercoat conductive layer 14B is integrated to the above-mentioned conductive layer 4 and hence omitted in the figures later.

Next, as illustrated in FIG. 9, the undercoat conductive layer 14A formed in a region excluding a predetermined circuit pattern is removed by etching to complete the conductive layer 4 with a predetermined circuit pattern on the undercoat insulating layer 3. It should be noted that an etchant such as a potassium permanganate-based etchant or a sodium metasilicate-based etchant as well as a potassium ferricyanide-based etchant is used for the etching of the thin film (undercoat conductive layer 14A) made of chromium or titanium, for example. Further, in the same manner as in the undercoat conductive layer 14B, the undercoat conductive layer 14A is also integrated to the above-mentioned conductive layer 4 and omitted in the figures later.

After that, as illustrated in FIG. 10, a hard nickel thin film 15 is formed on surfaces (upper surfaces) of the above-mentioned conductive layer 4 and stainless-steel foil substrate 2 by carrying out electroless nickel plating to cover and protect the surface of the conductive layer 4. The above-mentioned nickel thin film 15 has only to have such a thickness that the conductive layer 4 as a lower layer is not exposed, generally a thickness in the range of 0.05 to 1 μm.

It should be noted that the above-mentioned steps are steps common in the conductive layer 4 (wiring portion 4a, terminal portion 4b for control, and terminal portion 4c for a slider) to be formed on the substrate 2. Hereinafter, the conductive layer 4 on the left side of the figure is formed into the wiring portion 4a, and the terminal portion 4b (or 4c) is formed on the upper surface of the conductive layer 4 on the right side of the figure. Thus, such steps are described.

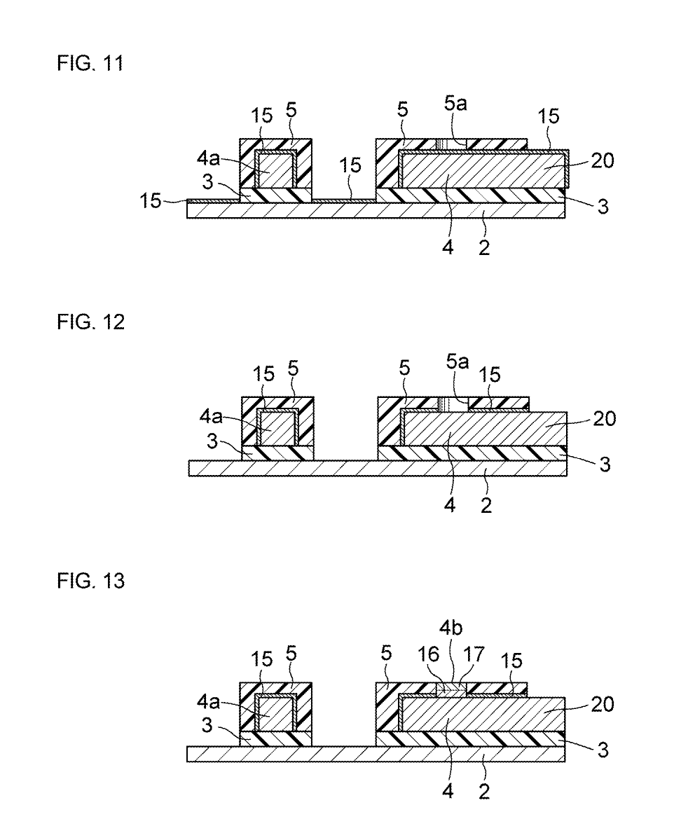

That is, as illustrated in FIG. 11, in the wiring portion 4a on the left side of the figure, in the same manner as in the formation of the undercoat insulating layer 3, the above-mentioned PI photosensitive resin composition is applied and formed into a film to form a cover insulating layer 5 for covering the wiring portion 4a. Meanwhile, also in the conductive layer 4 (on the right side of the figure) on which the terminal portion 4b is to be formed, the same PI photosensitive resin composition as the undercoat insulating layer 3 is applied and formed into a film, and by patterning using photolithography, the cover insulating layer 5 for covering the terminal portion 4b is formed so as to leave a predetermined region (generally an exposed surface formed on the bottom of a concave portion 5a having a circular or elliptical shape) for forming the terminal portion 4b on the upper surface of the conductive layer 4 and a lead portion 20 (exposed surface) for carrying out electrolytic plating as described later.

Next, as illustrated in FIG. 12, the nickel thin film 15 on the conductive layer 4 (on the right side of the figure) on which the terminal portion 4b is formed and the stainless-steel foil substrate 2 is removed. After that, the surface of the cover insulating layer 5 excluding the concave portion 5a for the above-mentioned terminal portion 4b and the surfaces of the undercoat insulating layer 3 and the stainless-steel foil substrate 2 are covered with a plating resist. Then, an electrode is connected to the above-mentioned lead portion 20, a nickel layer 16 and a gold layer 17 are successively laminated by electrolytic plating in the concave portion 5a of the above-mentioned cover insulating layer 5, to thereby form the terminal portion 4b. It should be noted that it is suitable that the above-mentioned nickel layer 16 have a thickness of 1 to 5 μm and the gold layer 17 have a thickness of about 0.05 to 1 μm. After that, as illustrated in FIG. 13, the above-mentioned plating resist is removed.

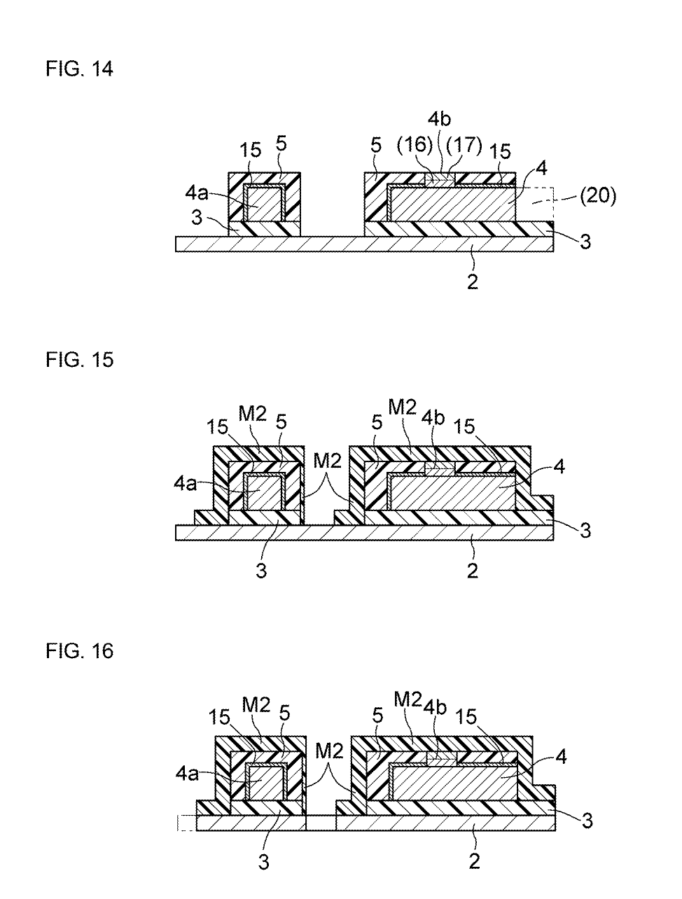

Next, as illustrated in FIG. 14, in the conductive layer 4 (on the right side of the figure) having formed thereon the above-mentioned terminal portion 4a, the lead portion 20 used for electrolytic plating is removed by chemical etching. The lead portion 20 (and integrated undercoat conductive layer 14A made of chromium or titanium) may be removed using a potassium ferricyanide-based etchant, a potassium permanganate-based etchant, or a sodium metasilicate-based etchant, or the like in the same manner as described above.

After that, in order to chemically etch the stainless-steel foil substrate 2 into a required shape, as illustrated in FIG. 15, a patterned mask M2 made of a photo resist, a dry film laminate, or the like is formed on the undercoat insulating layer 3 and the cover insulating layer 5.

Next, as illustrated in FIG. 16, the stainless-steel foil substrate 2 is etched into a required shape using a required etchant. The etchant to be used is, for example, an aqueous solution of ferric chloride, cupric chloride, or the like.

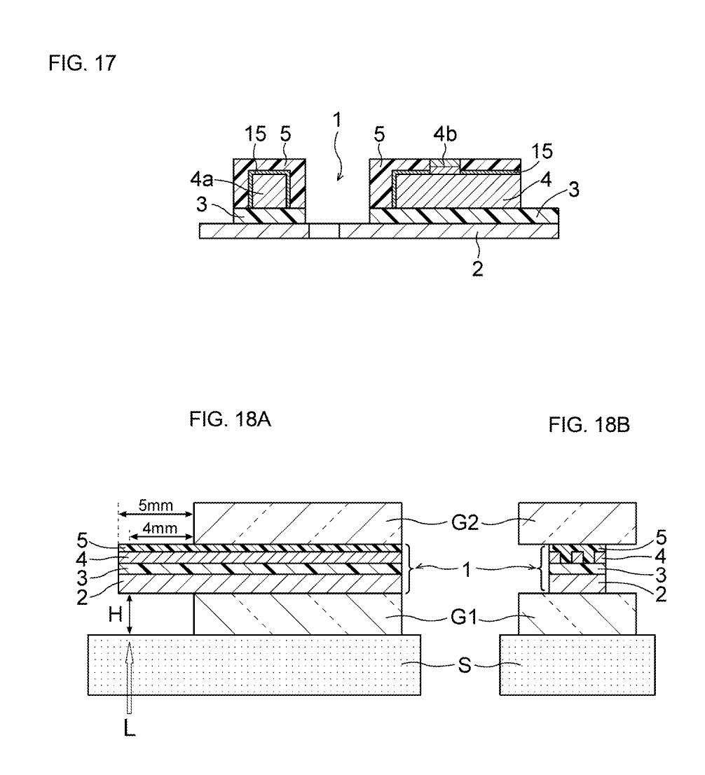

After the above-mentioned etching treatment, as illustrated in FIG. 17, the above-mentioned mask M2 is removed and washing with pure water and drying are carried out. Thus, a suspension board 1 with a circuit for use in a HDD according to this embodiment is obtained. That is, the suspension board 1 with a circuit for use in a HDD has the undercoat insulating layer 3 made of the PI photosensitive resin composition containing the component (A) and the component (B) on the stainless-steel foil substrate 2, and has formed thereon the conductive layer 4 with a predetermined circuit pattern made of copper. In addition, except for the terminal portion 4b (and 4c), the cover insulating layer 5 made of the above-mentioned PI photosensitive resin composition is provided on the above-mentioned conductive layer 4 to cover and protect the conductive layer 4.

Next, examples are described together with comparative examples. It should be noted that the present invention is by no means limited to the following examples.

### EXAMPLES

In the following examples, photosensitive resin compositions α1 to α4 made of polyimide precursors B1, B2, B3, or a carboxyl group-containing linear polymer D included in the component (B) and a 1,4-dihydropyridine derivative A described in the component (A) were used to form undercoat insulating layers and cover insulating layers. Thus, suspension boards with a circuit for use in a HDD of Examples 1 to 4 were produced. Further, photosensitive resin compositions β1 and β2 containing polyimide precursors C1 and C2 excluded from the component (B) were used to formundercoat insulating layers and cover insulating layers. Thus, suspension boards with a circuit for use in a HDD of Comparative Examples 1 and 2 were produced.

In addition, suspension boards with a circuit for use in a HDD of Examples 5 and 6 in each of which one of the undercoat insulating layer and the cover insulating layer was made using the photosensitive resin composition α1 and the other was made using the photosensitive resin composition β1, and a suspension board with a circuit for use in a HDD of Example 7 in which an insulating layer was constituted of three layers including an undercoat insulating layer, an intermediate insulating layer, and a cover insulating layer, and all the insulating layers were made using the photosensitive resin compositional were produced.

Then, those suspension boards with a circuit for use in a HDD (for test) of Examples 1 to 7 and Comparative Examples 1 and 2 were used to measure “warping” at 25° C. and 50% RH after production (completion) and a “change in PSA (attitude angle)” in the case of changing a humidity at 25° C. from 10% RH to 80% RH. The results were compared with each other.

First, polyimide precursors B1, B2, B3, C1, and C2 and a carboxyl group-containing linear polymer D constituting the respective photosensitive resin compositions were synthesized (polymerized). Next, a 1,4-dihydropyridine derivative A and an additive such as 1,3-diaza-2,4-cyclopentadiene (imidazole) or an assistant were added thereto and mixed and adjusted to produce solutions of photosensitive resin compositions α1 to α4 and photosensitive resin compositions β1 and β2 to be used for the formation of insulating layers of suspensions board with a circuit for use in a HDD of Examples 1 to 7 and Comparative Examples 1 and 2.

### <Synthesis of Polyimide Precursor B1>

35.5 g of a diamine (D-2000, manufactured by MITSUI FINE CHEMICAL Inc., n=33, approximate molecular weight: 2,000) represented by the following formula (10) and 19.4 g of 4,4′-diaminodiphenyl ether (hereinafter, “DDE”) were dissolved in 533 g of N-methyl-2-pyrrolidone (hereinafter, “NMP”), 25 g of pyromellitic acid dianhydride (hereinafter, “PMDA”) were added thereto, and the mixture was subjected to a reaction to afford a solution of a polyimide precursor B1.

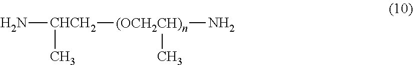

In the formula (10), n represents an integer of 2 or more, preferably 5 to 80, provided that n equals 33 in the above-mentioned diamine D-2000 and n equals 68 in the following diamine D-4000.

### <Synthesis of Polyimide Precursor B2>

27.5 g of a diamine (D-4000, manufactured by MITSUI FINE CHEMICAL Inc., compound in which n equals 68 in the above-mentioned formula (10), approximate molecular weight: 4,000) in place of the above-mentioned diamine D-2000, 15.2 g of DDE, 344 g of NMP, and 18.0 g of PMDA were subjected to the same reaction as in the polyimide precursor B1 to afford a solution of a polyimide precursor B2.

### <Synthesis of Polyimide Precursor B3>

27.2 g of a diamine (XJT-542, manufactured by MITSUI FINE CHEMICAL Inc., approximate molecular weight: 1,000) represented by the following formula (11) and 12.9 g of DDE were dissolved in 340 g of NMP, 20 g of PMDA were added thereto, and the mixture was subjected to a reaction to afford a solution of a polyimide precursor B3.

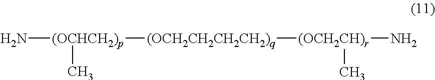

In the formula (11), p+r equals 6.0 and q equals 9.0.

### <Synthesis of Polyimide Precursor C1>

11.7 g of 1,4-diaminobenzene (PDA) and 8.5 g of 2,2′-bis(trifluoromethyl)-4,4′-diaminobiphenyl (TFMB) were dissolved in 340 g of NMP, and 39.8 g of 3,4,3′,4′-diphenyltetracarboxylic acid dianhydride (BPDA) were added thereto, and the mixture was subjected to a reaction to afford a solution of a polyimide precursor C1.

### <Synthesis of Polyimide Precursor C2>

29.2 g of a diamine (HF-BAPP) represented by the following formula (12) were dissolved in 340 g of NMP, 30.8 g of TA44BP represented by the following formula (13) were then added thereto, and the mixture was subjected to a reaction to afford a solution of a polyimide precursor C2.

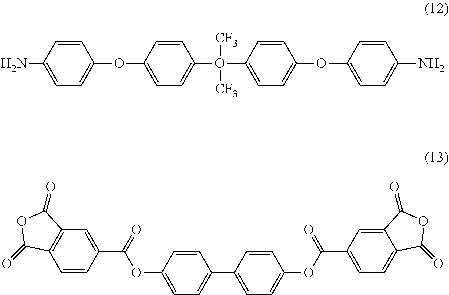

### <Synthesis of Carboxyl Group-Containing Linear Polymer D>

10 g of methacrylic acid, 80 g of butyl acrylate, 10 g of methyl methacrylate, 100 g of propylene glycol monomethyl ether acetate, and 1.0 g of azobisisobutyronitrile were loaded into a 300 ml separable flask under a nitrogen atmosphere, heated with stirring, and subjected to a reaction at 90° C. for 5 hours to afford a solution of a carboxyl group-containing linear polymer D (solids content: 50% by weight) (calculated value for carboxylic acid equivalent of carboxyl group-containing linear polymer D: 860, weight average molecular weight: 30,000).

### [1,4-Dihydropyridine Derivative A]

A compound in which R₁ represents C₂H₅ and R₂ and R₃ each represent CH₃ in the formula in the 1,4-dihydropyridine derivative [see the following formula (1)] described as the component (A).

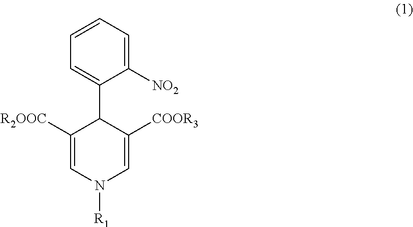

### [Preparation of Photosensitive Resin Composition]

Next, photosensitive resin compositions α1 to α4 and photosensitive resin compositions β1 and β2 each serving as a material for forming an insulating layer were prepared by blending and mixing the respective blend components shown in “Table 1” below at ratios shown in the table. It should be noted that figures (blending ratios) in Table 1 below refer to parts by weight of nonvolatile components and the figures in each row total in 100 parts by weight.

TABLE 1
(parts by weight)

| | Photosensitive | Photosensitive | Photosensitive | Photosensitive | Photosensitive | Photosensitive |
|---|---|---|---|---|---|---|
| | resin | resin | resin | resin | resin | resin |
| | composition | composition | composition | composition | composition | composition |
| Formulation | α1 | α2 | α3 | α4 | β1 | β2 |
| 1,4-Dihydropyridine derivative A | 13 | 13 | 13 | 5 | 7 | |
| Polyimide precursor B1 | 85 | | | | | |
| Polyimide precursor B2 | | 85 | | | | |
| Polyimide precursor B3 | | | 85 | | | |
| Polyimide precursor C1 | | | | | 73 | |
| Polyimide precursor C2 | | | | | | 100 |
| Carboxyl group-containing linear | | | | 83 | | |
| polymer D | | | | | | |
| Imidazole | 2 | 2 | 2 | | | |
| Epicoat YL980 (epoxy) | | | | 12 | | |
| ARONIX M-140 (acrylate) | | | | | 20 | |

Epicoat YL980: bisphenol A type epoxy resin manufactured by Mitsubishi Chemical Corporation
ARONIX M-140: 2-(1,2-cyclohexanedicarboximido) ethyl acrylate manufactured by TOAGOSEI CO. , LTD.

Next, a suspension board with a circuit for use in a HDD for evaluation was produced using the photosensitive resin composition prepared as described above.

### Production of Suspension Board with a Circuit for Evaluation

### Example 1

The above-mentioned photosensitive resin compositional (polyimide-based) was applied onto a stainless-steel (SUS304) foil substrate having a thickness of 18 μm and then dried with heating at 120° C. for 2 minutes to form a coating film of the photosensitive resin composition α1. Next, the coating film was irradiated with ultraviolet rays via a mask at an exposure dose of 700 mJ/cm², heated at 180° C. for 3 minutes, and then subjected to development with a developing solution containing 5% of tetramethylammonium hydroxide (TMAH)/45% of pure water/50% of ethanol at 30° C. for 2 minutes to form a positive type image. The resultant was further heated to 300° C. under vacuum at 0.01 torr to form a patterned undercoat insulating layer (having a thickness of 10 μm) made of a polyimide resin.

Part of the stainless-steel foil substrate provided with the undercoat insulating layer obtained above was cut out and then immersed in a ferric chloride etchant and the stainless-steel foil was removed to afford an insulating layer (film) having a thickness of 10 μm. The film was used to measure and confirm the tensile storage modulus at 25° C., coefficient of thermal expansion, and coefficient of hygroscopic expansion of the insulating layer by a method described later.

Next, chromium and copper thin films were formed so as to have thicknesses of 30 nm (chromium)/70 nm (copper), respectively, on the residual undercoat insulating layer on the stainless-steel foil substrate by sputtering treatment, and electrolytic copper plating was carried out so that a conductive layer having a thickness of 10 μm was formed on the copper thin film. Then, exposure and developing treatment were carried out by a patterning technology using a dry film resist. After that, the conductive layer made of copper excluding a circuit pattern portion was removed by etching, the dry film resist was removed, and then the chromium thin film was removed by etching so that a conductive layer with a circuit pattern of a core width/core-core interval=50/50 μm was obtained on the undercoat insulating layer.

Next, electroless nickel plating was carried out with a thickness of 0.1 μm on a surface of the conductive layer with a circuit pattern to cover and protect the surface of the conductive layer made of copper. After that, again, a positive type cover insulating layer (having a thickness of 5 μm on the conductive layer) was formed by the same method as in the above-mentioned undercoat insulating layer using the photosensitive resin compositional and then subjected to exposure and development using a dry film resist, to thereby form a required pattern on the stainless-steel foil substrate. Then, the stainless-steel foil substrate was immersed in a ferric chloride etchant to afford a suspension board with a circuit for evaluation (Example 1: total thickness: 43 μm) having a size of 5×30 mm.

### Example 2

A suspension board with a circuit for evaluation (Example 2) having a size of 5×30 mm was produced in the same manner as in Example 1 except that a photosensitive resin composition α2 (polyimide-based) was used in place of the photosensitive resin compositional. It should be noted that, in the same manner as in Example 1, in the course of production, part of the stainless-steel foil substrate provided with the undercoat insulating layer was cut out and the stainless-steel foil was removed to produce an insulating layer (film) having a thickness of 10 μm. The film was used to measure the tensile storage modulus at 25° C., coefficient of thermal expansion, and coefficient of hygroscopic expansion of the insulating layer.

### Example 3

A suspension board with a circuit for evaluation (Example 3) having a size of 5×30 mm was produced in the same manner as in Example except that: a photosensitive resin composition α3 (polyimide-based) was used in place of the photosensitive resin composition α1; and each insulating layer was formed as a negative type image using a mask having an opposite opening pattern to that in Example 1. It should be noted that, in the same manner as in Example 1, in the course of production, part of the stainless-steel foil substrate provided with the undercoat insulating layer was cut out and the stainless-steel foil was removed to produce an insulating layer (film) having a thickness of 10 μm. The film was used to measure the tensile storage modulus at 25° C., coefficient of thermal expansion, and coefficient of hygroscopic expansion of the insulating layer.

### Example 4

A photosensitive resin composition α4 (epoxy-based) was applied onto a stainless-steel (SUS304) foil substrate having a thickness of 18 μm and then dried with heating at 100° C. for 3 minutes to form a coating film of the photosensitive resin composition α4. Next, the coating film was irradiated with ultraviolet rays via a mask at an exposure dose of 500 mJ/cm², heated at 110° C. for 5 minutes, and then subjected to development with a 1% sodium carbonate aqueous solution (developing solution) at 30° C. for 2 minutes to form a negative type image. The resultant was further heated to 150° C. to form a patterned undercoat insulating layer (having a thickness of 10 μm).

Part of the stainless-steel foil substrate provided with the undercoat insulating layer obtained above was cut out and then immersed in a ferric chloride etchant and the stainless-steel foil was removed to afford an insulating layer (film) having a thickness of 10 μm. The film was used to measure and confirm the tensile storage modulus at 25° C., coefficient of thermal expansion, and coefficient of hygroscopic expansion of the insulating layer by a method described later.

Next, chromium and copper thin films were formed so as to have thicknesses of 30 nm (chromium)/70 nm (copper), respectively, on the residual undercoat insulating layer on the stainless-steel foil substrate by sputtering treatment, and electrolytic copper plating was carried out so that a conductive layer having a thickness of 10 μm was formed on the copper thin film. Next, exposure and developing treatment were carried out by a patterning technology using a dry film resist. After that, the conductive layer made of copper excluding a circuit pattern portion was removed by etching, the dry film resist was removed, and then the chromium thin film was removed by etching so that a conductive layer with a circuit pattern of a core width/core-core interval=50/50 μm was obtained on the undercoat insulating layer.

Next, electroless nickel plating was carried out with a thickness of 0.1 μm on a surface of the conductive layer with a circuit pattern to cover and protect the surface of the conductive layer made of copper. After that, again, a negative type cover insulating layer (having a thickness of 5 μm on the conductive layer) was formed by the same method as in the above-mentioned undercoat insulating layer using the photosensitive resin composition α4 and then subjected to exposure and development using a dry film resist, to thereby form a required pattern on the stainless-steel foil substrate. Then, the stainless-steel foil substrate was immersed in a ferric chloride etchant to afford a suspension board with a circuit for evaluation (Example 4) having a size of 5×30 mm.

### Comparative Example 1

A suspension board with a circuit for evaluation (Comparative Example 1) having a size of 5×30 mm was produced in the same manner as in Example 1 except that: a photosensitive resin composition β1 (polyimide-based) for comparison was used in place of the photosensitive resin composition α1; and each insulating layer was formed as a negative type image using a mask having an opposite opening pattern to that in Example 1. It should be noted that, in the same manner as in Example 1, in the course of production, part of the stainless-steel foil substrate provided with the undercoat insulating layer was cut out and the stainless-steel foil was removed to produce an insulating layer (film) having a thickness of 10 μm. The film was used to measure the tensile storage modulus at 25° C., coefficient of thermal expansion, and coefficient of hygroscopic expansion of the insulating layer.

### Comparative Example 2

A photosensitive resin composition 132 (polyimide-based) for comparison was applied onto a stainless-steel (SUS304) foil substrate having a thickness of 18 μm and then heated to 400° C. to form an undercoat insulating layer (having a thickness of 10 μm) made of a polyimide resin.

Part of the stainless-steel foil substrate provided with the undercoat insulating layer obtained above was cut out and then immersed in a ferric chloride etchant and the stainless-steel foil was removed to afford an insulating layer (film) having a thickness of 10 μm. The film was used to measure and confirm the tensile storage modulus at 25° C., coefficient of thermal expansion, and coefficient of hygroscopic expansion of the insulating layer by a method described later.

Next, chromium and copper thin films were formed so as to have thicknesses of 30 nm (chromium)/70 nm (copper), respectively, on the residual undercoat insulating layer on the stainless-steel foil substrate by sputtering treatment, and electrolytic copper plating was carried out so that a conductive layer having a thickness of 10 μm was formed on the copper thin film. Next, exposure and developing treatment were carried out by a patterning technology using a dry film resist. After that, the copper conductive layer excluding a circuit pattern portion was removed by etching, the dry film resist was removed, and then the chromium thin film was removed by etching so that a conductive layer with a circuit pattern of a core width/core-core interval=50/50 μm was obtained on the undercoat insulating layer.

Next, electroless nickel plating was carried out with a thickness of 0.1 μm on a surface of the conductive layer with a circuit pattern to cover and protect the surface of the copper conductive layer. After that, again, a cover insulating layer (having a thickness of 5 μm on the conductive layer) was formed by curing by the same method as in the above-mentioned undercoat insulating layer using the photosensitive resin composition 132 and then subjected to exposure and development using a dry film resist, to thereby form a required pattern on the cover insulating layer. Then, an unnecessary cover insulating layer was removed using a polyimide etchant.

Next, a required pattern was formed on the stainless-steel foil substrate using a dry film resist, and then the stainless-steel foil substrate was immersed in a ferric chloride etchant to afford a suspension board with a circuit for evaluation (Comparative Example 2) having a size of 5×30 mm.

### Example 5

A negative type undercoat insulating layer (having a thickness of 10 μm) was formed on a stainless-steel (SUS304) foil substrate having a thickness of 18 μm in the same manner as in Comparative Example 1 using the photosensitive resin composition 132 (polyimide-based) for comparison. It should be noted that the tensile storage modulus at 25° C., coefficient of thermal expansion, and coefficient of hygroscopic expansion of the undercoat insulating layer are equivalent to those of the insulating layer of Comparative Example 1.

Next, in the same manner as in Example 1, a conductive layer with a circuit pattern of a core width/core-core interval=50/50 μm was obtained on the residual undercoat insulating layer on the stainless-steel foil substrate. Then, electroless nickel plating was carried out with a thickness of 0.1 μm on a surface of the conductive layer with a circuit pattern to cover and protect the surface of the copper conductive layer. After that, a positive type cover insulating layer (having a thickness of 5 μm on the conductive layer) was formed in the same manner as in Example 1 using the photosensitive resin composition α1 (polyimide-based). It should be noted that the tensile storage modulus at 25° C., coefficient of thermal expansion, and coefficient of hygroscopic expansion of the cover insulating layer are conceivable to be equivalent to those of the insulating layer of Example 1.

Next, exposure and development were carried out using a dry film resist to form a required pattern on the stainless-steel foil substrate. After that, the stainless-steel foil substrate was immersed in a ferric chloride etchant to afford a suspension board with a circuit for evaluation (Example 5) having a size of 5×30 mm. As described above, the suspension board with a circuit for evaluation of Example 5 above has an undercoat insulating layer formed using the photosensitive resin composition for Comparative Example 1 and has a cover insulating layer formed using the photosensitive resin composition for Example 1.

### Example 6

A positive type undercoat insulating layer (having a thickness of 10 μm) was formed on a stainless-steel (SUS304) foil substrate having a thickness of 18 μm in the same manner as in Example 1 using the photosensitive resin compositional (polyimide-based). It should be noted that the tensile storage modulus at 25° C., coefficient of thermal expansion, and coefficient of hygroscopic expansion of the undercoat insulating layer are equivalent to those of the insulating layer of Example 1.

Next, in the same manner as in Example 1, a conductive layer with a circuit pattern of a core width/core-core interval=50/50 μm was obtained on the residual undercoat insulating layer on the stainless-steel foil substrate. Next, electroless nickel plating was carried out with a thickness of 0.1 μm on a surface of the conductive layer with a circuit pattern to cover and protect the surface of the copper conductive layer. After that, a negative type cover insulating layer (having a thickness of 5 μm on the conductive layer) was formed in the same manner as in Comparative Example 1 using the photosensitive resin composition β2 (polyimide-based) for comparison. It should be noted that the tensile storage modulus at 25° C., coefficient of thermal expansion, and coefficient of hygroscopic expansion of the cover insulating layer are conceivable to be equivalent to those of the insulating layer of the Comparative Example 1.

Next, exposure and development were carried out using a dry film resist to form a required pattern on the stainless-steel foil substrate. Then, the stainless-steel foil substrate was immersed in a ferric chloride etchant to afford a suspension board with a circuit for evaluation (Example 6) having a size of 5×30 mm. As described above, on the contrary to Example 5, the suspension board with a circuit for evaluation of Example 6 has an undercoat insulating layer formed using the photosensitive resin composition for Example 1 and has a cover insulating layer formed using the photosensitive resin composition for Comparative Example 1.

### Example 7

The above-mentioned photosensitive resin compositional (polyimide-based) was applied onto a stainless-steel (SUS304) foil substrate having a thickness of 18 μm and then dried with heating at 120° C. for 2 minutes to form a coating film of the photosensitive resin compositional. Next, the resultant was irradiated with ultraviolet rays via a mask at an exposure dose of 700 mJ/cm², heated at 180° C. for 3 minutes, and then subjected to development with a developing solution containing 5% of tetramethylammonium hydroxide (TMAH)/45% of pure water/50% of ethanol at 30° C. for 2 minutes to form a positive type image. The resultant was further heated to 300° C. under vacuum at 0.01 torr to form a patterned undercoat insulating layer made of a polyimide resin (having a thickness of 5 μm). It should be noted that the tensile storage modulus at 25° C., coefficient of thermal expansion, and coefficient of hygroscopic expansion of the undercoat insulating layer are equivalent to those of the insulating layer of Example 1.

Next, chromium and copper thin films were formed so as to have thicknesses of 30 nm (chromium)/70 nm (copper), respectively, on the undercoat insulating layer by sputtering treatment, and electrolytic copper plating was carried out so that a first conductive layer having a thickness of 5 μm was formed on the copper thin film. Next, exposure and developing treatment were carried out by a patterning technology using a dry film resist. After that, the conductive layer made of copper excluding a circuit pattern portion was removed by etching, the dry film resist was removed, and then the chromium thin film was removed by etching so that a first conductive layer with a circuit pattern of a core width/core-core interval=50/50 μm was obtained on the undercoat insulating layer. Then, electroless nickel plating was carried out with a thickness of 0.1 μm on a surface of the first conductive layer to cover and protect the surface of the first conductive layer.

Next, a positive type intermediate insulating layer (having a thickness of 5 μm on the first conductive layer) was formed on the first conductive layer by the same method as in the above-mentioned undercoat insulating layer using the photosensitive resin compositional. Next, a second conductive layer with a circuit pattern formed of a copper thin film having a thickness of 5 μm was formed on the above-mentioned intermediate insulating layer by the same method as in the above-mentioned first conductive layer, and electroless nickel plating was carried out with a thickness of 0.1 μm on a surface of the second conductive layer to cover and protect the surface.

After that, again, a positive type cover insulating layer (having a thickness of 5 μm on the second conductive layer) was formed by the same method as in the above-mentioned undercoat insulating layer and intermediate insulating layer using the photosensitive resin compositional and then subjected to exposure and development using a dry film resist, to thereby form a required pattern on the stainless-steel foil substrate. After that, the stainless-steel foil substrate was immersed in a ferric chloride etchant to afford a suspension board with a circuit for evaluation (Example 7: total thickness: 43 μm) having a size of 5×30 mm. The suspension board with a circuit for evaluation of Example 7 includes three insulating layers, i.e., an undercoat insulating layer, an intermediate insulating layer, and a cover insulating layer, all of which are formed using the photosensitive resin composition for Example 1. It should be noted that all of the tensile storage modulus at 25° C., coefficient of thermal expansion, and coefficient of hygroscopic expansion of the above-mentioned intermediate insulating layer and cover insulating layer are conceivable to be equivalent to those of the insulating layer of Example 1.

### <<Tensile Storage Modulus at 25° C.>>

As described above, in the course of the production of each of the suspension boards with a circuit for evaluation of Examples 1 to 4 and Comparative Examples 1 and 2, the undercoat insulating layer after curing was measured for its tensile storage modulus at 25° C. In order to measure the tensile storage modulus, first, the stainless-steel foil substrate is peeled off from the undercoat insulating layer as described above to produce a film-like insulating layer. The film-like insulating layer is cut into apiece measuring 5 mm wide by 30 mm long to produce a sample for measurement. Then, the above-mentioned film-like insulating layer was measured for its dynamic viscoelasticity (E′) while drawing the layer under the condition of a frequency of 1 Hz in the range of 0 to 50° C. (temperature rising rate 5° C./min) using a viscoelasticity measurement device RSA III (manufactured by Rheometric Scientific). Then, a value at 25° C. (unit: Pa) was read.

It should be noted that, for reference, the same sample as the above-mentioned film-like insulating layer was used to measure a “coefficient of hygroscopic expansion” and a “coefficient of thermal expansion.” “Table 2” below shows those results together with those of the above-mentioned “tensile storage modulus at 25° C.”

### <<Coefficient of Hygroscopic Expansion>>

A coefficient of hygroscopic expansion (unit: ppm/RH %) was determined by measuring the elongation of each insulating layer in the case of changing a humidity at 25° C. from 10% RH to 80% RH using a humidity-controlled thermomechanical analyzer HC-TMA4000SA (manufactured by Bruker AXS).

### <<Coefficient of Thermal Expansion>>

A coefficient of thermal expansion (unit: ppm/K) was determined by measuring the elongation of each insulating layer in the case of changing a temperature from 25° C. to 60° C. using a thermomechanical analyzer TMA 8310 (manufactured by Rigaku Corporation).

Further, each of the resultant suspension boards with a circuit for evaluation was used to measure “warping” at 25° C. and 50% RH and a “change in PSA (attitude angle)” in the case of changing a humidity at 25° C. from 10% RH to 80% RH.

### <<Warping>>

Each of the suspension boards with a circuit for evaluation (measuring 5×30 mm) of Examples 1 to 4 and Comparative Examples 1 and 2 above was mounted on a flat glass plate to measure a height (mm) from the upper surface of the glass plate to the highest site of the suspension board with a circuit for evaluation. In the evaluation of warping, a case where the height is less than 1 mm is expressed as a symbol of acceptable “o”, and a case where the height is 1 mm or more is expressed as a symbol of unacceptable “×”.

### <<Change in PSA>>

As described above, each of the above-mentioned suspension boards 1 with a circuit for evaluation has the undercoat insulating layer (having a thickness of 10 μm) 3, the conductive layer (having a thickness of 10 μm) 4 made of copper, and the cover insulating layer (having a thickness of 5 μm) 5 successively laminated on the stainless-steel foil substrate (having a thickness of 18 μm) 2 and has been cut into a strip measuring 5 mm wide by 30 mm long.

In the preparation for the measurement of a change in PSA, first, as illustrated in FIGS. 18A and 18B, a sample (board 1) was set at a predetermined position in a measurement device while being sandwiched between two slide glasses (each having a thickness of 1 mm) G1 and G2, and the entire device was then placed in a thermohygrostat. It should be noted that a symbol S represents a measurement stage made of glass in the figures.

Next, the interior of the thermohygrostat was adjusted to 25° C.×10% RH and the sample was left until being stabilized. After the stabilization of a temperature and a humidity, as illustrated in FIG. 18A, at the point of 4 mm away from ends of the above-mentioned two slide glasses G1 and G2, the sample was irradiated with laser light (open arrow) L through the measurement stage S, and based on the reflection, a distance H₁₀ (μm) between the measurement stage S and the back surface (stainless-steel foil substrate 2) of the board 1 at 10% RH was measured.

Next, the interior of the thermohygrostat was adjusted to 25° C.×80% RH and the sample was left until being stabilized similarly. After the stabilization of a temperature and a humidity, in the same manner as described above, the sample was irradiated with laser light L, and based on the reflection, a distance H₈₀ (μm) between the measurement stage S and the back surface of the board 1 at 80% RH was measured.

Then, a difference LH (μm) between a distance H₁₀ at 25° C.×10% RH and a distance H₈₀ at 25° C.×80% RH was determined to calculate a change in PSA using the following equation.

Change in PSA(deg/%RH)=A TAN(ΔH/4000)/π×180/70

(provided that ΔH=|H₈₀−H₁₀|)

In the evaluation of a change in PSA, a value of less than 0.002 is expressed as a symbol of excellent “oo”, a value of 0.002 or more and less than 0.006 is expressed as a symbol of acceptable “o”, a value of 0.006 or more is expressed as a symbol of unacceptable “×”. “Table 2” below shows the results.

TABLE 2

| | Example | | | | | | | Comparative Example | |
|---|---|---|---|---|---|---|---|---|---|
| Measurement items | 1 | 2 | 3 | 4 | 5 | 6 | 7 | 1 | 2 |
| Tensile storage modulus | 0.40 | 0.90 | 0.12 | 0.40 | — | — | — | 7.0 | 5.0 |
| at 25° C. (GPa) | | | | | | | | | |
| Warping | ∘ | ∘ | ∘ | ∘ | — | — | — | ∘ | x |
| Change in PSA | ∘∘ | ∘ | ∘∘ | ∘∘ | ∘ | ∘ | ∘∘ | x | ∘ |
| <Ref.> Coefficient of | 80 | 70 | 80 | 90 | — | — | — | 13 | 5 |
| hygroscopic expansion | | | | | | | | | |
| (ppm/% RH) | | | | | | | | | |
| <Ref.> Coefficient of | 100 | 90 | 90 | 100 | — | — | — | 18 | 30 |
| thermal expansion (ppm/K) | | | | | | | | | |

The results of the suspension boards with a circuit for evaluation of Examples 1 to 7 in “Table 2” above reveal that warping after board formation occurs to a less extent and a change in PSA (attitude angle) during a change in humidity is suppressed in the suspension boards in each of which at least one of the undercoat insulating layer 3 and the cover insulating layer 5 has a tensile storage modulus at 25° C. in the range of 0.1 to 1.0 GPa.

In contrast, the suspension boards with a circuit for evaluation of Comparative Examples 1 and 2 each have a lower coefficient of hygroscopic expansion than the suspension boards with a circuit for evaluation of Examples 1 to 7, but show larger warping after board formation and a larger change in PSA during a change in humidity than the above-mentioned suspension boards of Examples 1 to 7, and hence are found to be sensitive to a humidity.

Although a specific form of embodiment of the instant invention has been described above and illustrated in the accompanying drawings in order to be more clearly understood, the above description is made by way of example and not as a limitation to the scope of the instant invention. It is contemplated that various modifications apparent to one of ordinary skill in the art could be made without departing from the scope of the invention.

The suspension board with a circuit according to the present invention is small in expansion or shrinkage due to a change in humidity, and hence is suitable for a suspension board with a circuit for use in a hard disk drive device, which requires supporting a slider including a magnetic head in a stable and highly precise manner.

What is claimed is:

1. A suspension board, comprising:
a substrate made of metal;
an undercoat insulating layer provided on the substrate made of metal;
a conductive layer formed of a predetermined wiring circuit pattern provided on the undercoat insulating layer; and
a cover insulating layer provided so as to cover the conductive layer,
wherein at least one of the undercoat insulating layer and the cover insulating layer has a tensile storage modulus at 25° C. of 0.1 to 1.0 GPa.

2. The suspension board according to claim 1, wherein the undercoat insulating layer and the cover insulating layer each have a tensile storage modulus at 25° C. of 0.1 to 1.0 GPa.

3. The suspension board according to claim 1, wherein the undercoat insulating layer and the cover insulating layer are each made of a photosensitive resin composition containing the following component (A) and component (B):
(A) a 1,4-dihydropyridine derivative represented by the following general formula (1): 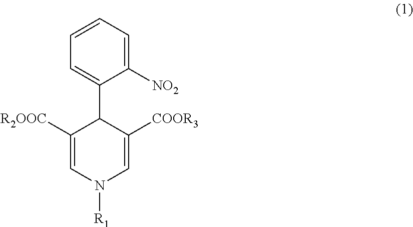
where R₁ represents an alkyl group having 1 to 3 carbon atoms; and
R₂ and R₃ each represent a hydrogen atom or an alkyl group having 1 or 2 carbon atoms and may be identical to or different from each other; and
(B) a polyimide resin obtained by a reaction of a tetracarboxylic acid dianhydride and a diamine compound which has two terminals each having an amine structure and has a polyether structure, or a precursor resin thereof.

4. The suspension board according to claim 2, wherein the undercoat insulating layer and the cover insulating layer are each made of a photosensitive resin composition containing the following component (A) and component (B):
(A) a 1,4-dihydropyridine derivative represented in the general formula (1); and
(B) a polyimide resin obtained by a reaction of a tetracarboxylic acid dianhydride and a diamine compound which has two terminals each having an amine structure and has a polyether structure, or a precursor resin thereof.

5. A suspension board, comprising:
a substrate made of metal;
an undercoat insulating layer provided on the substrate made of metal;
a first conductive layer formed of a predetermined wiring circuit pattern provided on the undercoat insulating layer;
an intermediate insulating layer provided on the first conductive layer;
a second conductive layer formed of a predetermined wiring circuit pattern provided on the intermediate insulating layer; and
a cover insulating layer provided on the second conductive layer,
wherein at least one insulating layer of the undercoat insulating layer, the intermediate insulating layer, and the cover insulating layer has a tensile storage modulus at 25° C. of 0.1 to 1.0 GPa.

6. The suspension board according to claim 5, wherein all of the undercoat insulating layer, the intermediate insulating layer, and the cover insulating layer have a tensile storage modulus at 25° C. of 0.1 to 1.0 GPa.

7. The suspension board according to claim 5, wherein the undercoat insulating layer, the intermediate insulating layer, and the cover insulating layer are each made of a photosensitive resin composition containing the following component (A) and component (B):
(A) a 1,4-dihydropyridine derivative represented by the following general formula (1). 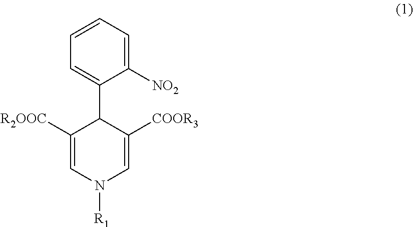
where R₁ represents an alkyl group having 1 to 3 carbon atoms; and
R₂ and R₃ each represent a hydrogen atom or an alkyl group having 1 or 2 carbon atoms and may be identical to or different from each other; and
(B) a polyimide resin obtained by a reaction of a tetracarboxylic acid dianhydride and a diamine compound which has two terminals each having an amine structure and has a polyether structure, or a precursor resin thereof.

8. The suspension board according to claim 6, wherein the undercoat insulating layer, the intermediate insulating layer, and the cover insulating layer are each made of a photosensitive resin composition containing the following component (A) and component (B):
(A) a 1,4-dihydropyridine derivative represented in the general formula (1); and
(B) a polyimide resin obtained by a reaction of a tetracarboxylic acid dianhydride and a diamine compound which has two terminals each having an amine structure and has a polyether structure, or a precursor resin thereof.
